(19) United States
(12) Patent Application Publication
(10) Pub. No.: US 2021/0345525 A1
(43) Pub. Date: Nov. 4, 2021

(54) FASTENING DEVICE AND HEAT DISSIPATION MODULE WITH THE SAME

(71) Applicant: Auras Technology Co., Ltd., New Taipei City (TW)

(72) Inventors: Hong-Long CHEN, New Taipei City (TW); Cheng-Ju CHANG, New Taipei City (TW); Ming-Yuan LO, New Taipei City (TW); Ching-An LIU, New Taipei City (TW)

(21) Appl. No.: 17/109,773

(22) Filed: Dec. 2, 2020

Related U.S. Application Data
(60) Provisional application No. 63/017,321, filed on Apr. 29, 2020.

(30) Foreign Application Priority Data
Jul. 22, 2020 (TW) 109209410

(51) Int. Cl. H05K 7/20

(52) U.S. Cl. CPC H05K 7/20418; H05K 7/20709

(57) ABSTRACT

A fastening device includes a fixing nut and a fixing base. The fixing base includes a base plate, an anti-falling wall, a door piece, and an anti-tilt arm. The anti-falling wall, the door piece and the anti-tilt arm are formed on the base plate, and the anti-tilt arm is arranged opposite to the door piece. An accommodation space is formed between the anti-falling wall, the door piece and the anti-tilt arm, and the fixing nut is rotatably arranged in the accommodation space. In addition, a heat dissipation module with the fastening device is also disclosed herein.

### RELATED APPLICATIONS

This application claims priority to U.S. Provisional Application Ser. No. 63/017,321, filed Apr. 29, 2020, and Taiwan Application Serial Number 109209410, filed Jul. 22, 2020, the disclosures of which are incorporated herein by reference in their entireties.

### TECHNICAL FIELD

The present disclosure generally relates to a fastening device. More particularly, the present disclosure relates to a fastening device of a heat dissipation module.

### BACKGROUND

With the increasing computing capability of computers, the temperature control of electronic components such as central processing units and other electronic components is becoming more and more important. At present, most computers with high-speed computing performance use active heat dissipation modules in the chassis. In other words, the heat dissipation module basically includes a fan, a heat pipe and heat dissipation fins. The heat pipe is connected to a heat source, i.e. a central processing unit, and the heat pipe is attached to the heat dissipation fins to transfer heat from the heat source to the heat dissipation fins therethrough. The heat dissipation fins are assembled at an air outlet of the fan. When the fan blades rotate, the heat of the heat dissipation fins is discharged from the computer by the airflow blown from the air outlet to maintain the working stability of the electronic component.

However, at present, with modularized heat dissipation devices, fastening devices and screws are often utilized to fix the heat dissipation device to a carrier board. Although current fastening devices are convenient to install, the fixing nut of the fastening device may fall off during the transportation. Therefore, the defective rate of the heat dissipation module is increased, which brings trouble to the computer manufacturers.

There is a need to effectively prevent the fixing nut of the heat dissipation module from falling off so as to improve the production efficiency and yield of the heat dissipation modules and the computers, and further reduce the production cost for manufacturing the computers.

### SUMMARY

One objective of the embodiments of the present invention is to provide a fastening device able to prevent a fixing nut from falling off to improve the production efficiency and yield of the heat dissipation modules and the computers so as to reduce the computer manufacturing cost.

To achieve these and other advantages and in accordance with the objective of the embodiments of the present invention, as the embodiment broadly describes herein, the embodiments of the present invention provides a fastening device including a fixing nut and a fixing base. The fixing base includes a base plate, an anti-falling wall, a door piece, and an anti-tilt arm. The anti-falling wall, the door piece and the anti-tilt arm are formed on the base plate, and the anti-tilt arm is disposed opposite to the door piece. The anti-falling wall, the door piece and the anti-tilt arm form an accommodation space, and the fixing nut is rotatably disposed in the accommodation space.

In some embodiments, the fixing base further includes an elastic claw formed on a surface, opposite to the anti-tilt arm, of the base plate.

In some embodiments, the fastening device further includes at least one metal fixing hook movably mounted on the fixing base.

In some embodiments, the anti-tilt arm includes a first flange protruding toward the fixing nut.

In some embodiments, the anti-falling wall includes a second flange protruding toward the fixing nut.

In some embodiments, an anti-tilt arm height of the anti-tilt arm is equal to about 50% to 80% of a nut height of the fixing nut.

In some embodiments, an anti-falling wall height of the anti-falling wall is equal to about 30% to 50% of the nut height of the fixing nut.

In some embodiments, a door piece height of the door piece is equal to about 20% to 35% of the nut height of the fixing nut.

In some embodiments, a height difference between an anti-drop flange bottom height of the anti-falling wall and the door piece height is smaller than a flange height of the fixing nut.

According to another aspect of the present invention, there is provided a heat dissipation module including a base board, a heat pipe, a metal heat dissipation block, a plurality of heat dissipation fins and a plurality of fastening devices. The heat pipe is disposed on the base board, the metal heat dissipation block is fixed on a surface of the heat pipe, the heat dissipation fins are fixed on the base board, the fastening devices are fixed on the base board, and the base board is fixed on a carrier board with a plurality of fixing screws.

Hence, the fastening device can conveniently fix the heat dissipation module on the carrier board, and the fastening device can be quickly fixed on the base board with the elastic claws. In addition, the fastening device utilizes the anti-tilt arm to effectively limit the tilt angle of the fixing nut, so as to prevent the fixing nut accidentally falling off the fixing base before the fixing nut is fixed to the carrier board.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates a schematic perspective diagram showing a fastening device according to one embodiment of the present invention;

FIG. 2 illustrates a partial perspective diagram showing a heat dissipation module according to one embodiment of the present invention;

FIG. 3 illustrates a schematic perspective diagram showing the heat dissipation module of FIG. 2 viewed from another angle;

FIG. 4 illustrates a schematic perspective diagram showing a fixing base of the fastening device of FIG. 2;

FIG. 5 illustrates a side view showing a fixing base and a fixing nut of the fastening device of FIG. 1; and

FIG. 6 illustrates a side view showing a carrier board equipped with the heat dissipation module.

### DETAILED DESCRIPTION OF THE PREFERRED EMBODIMENT

The following description is of the best presently contemplated mode of carrying out the present disclosure. This description is not to be taken in a limiting sense but is made merely for the purpose of describing the general principles of the invention. The scope of the invention should be determined by referencing the appended claims.

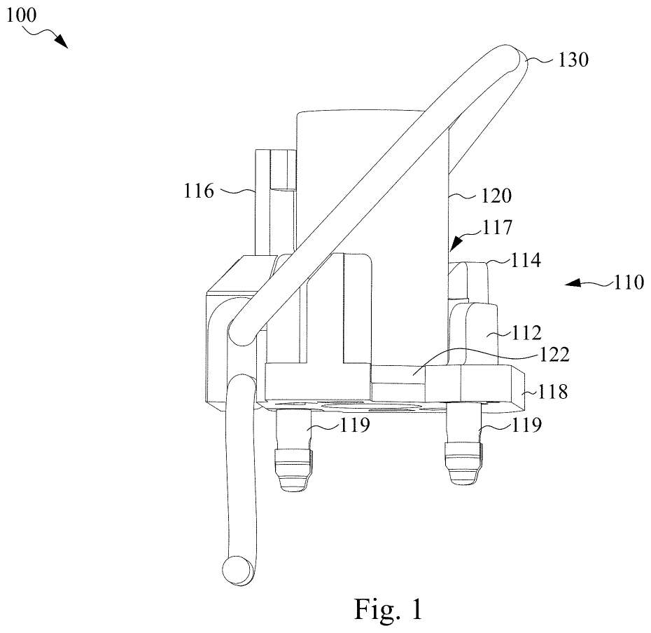

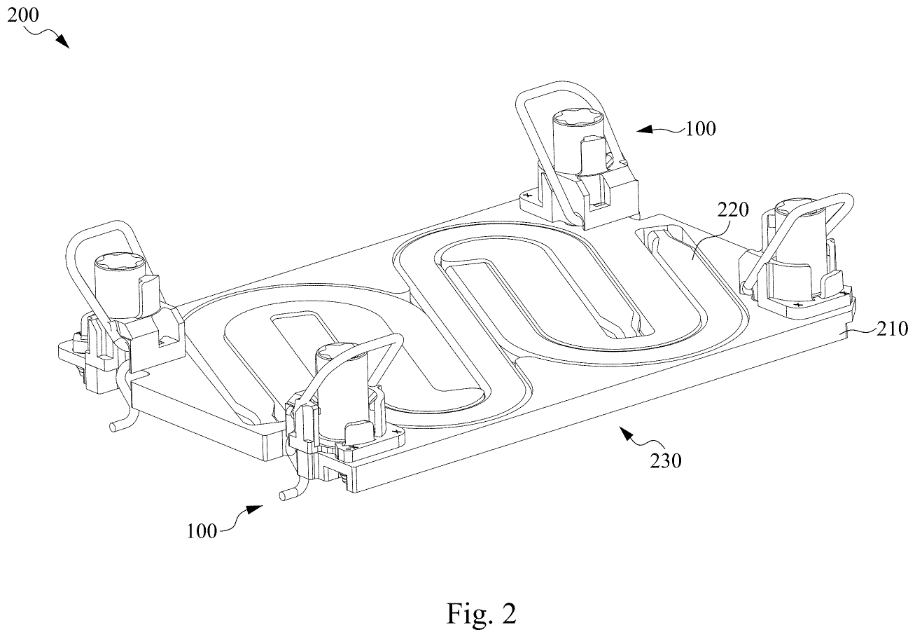

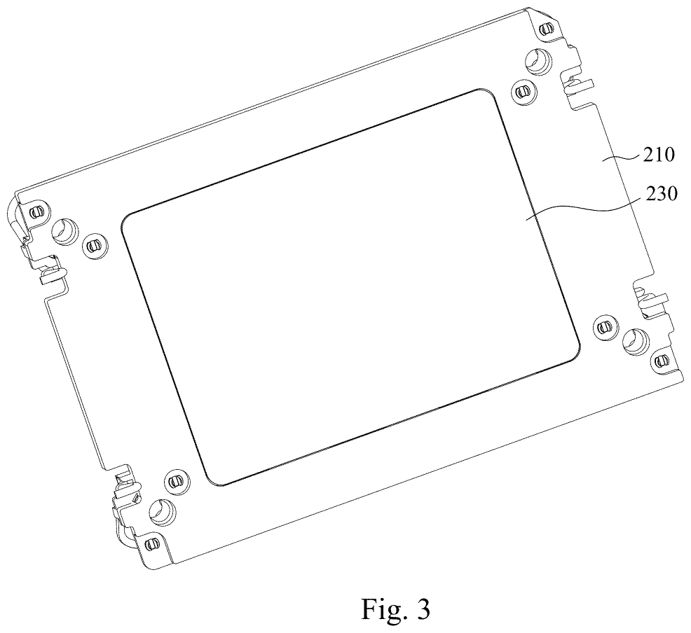

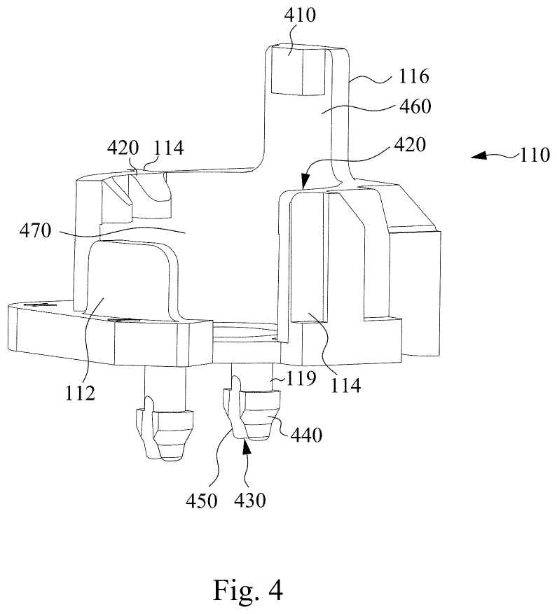

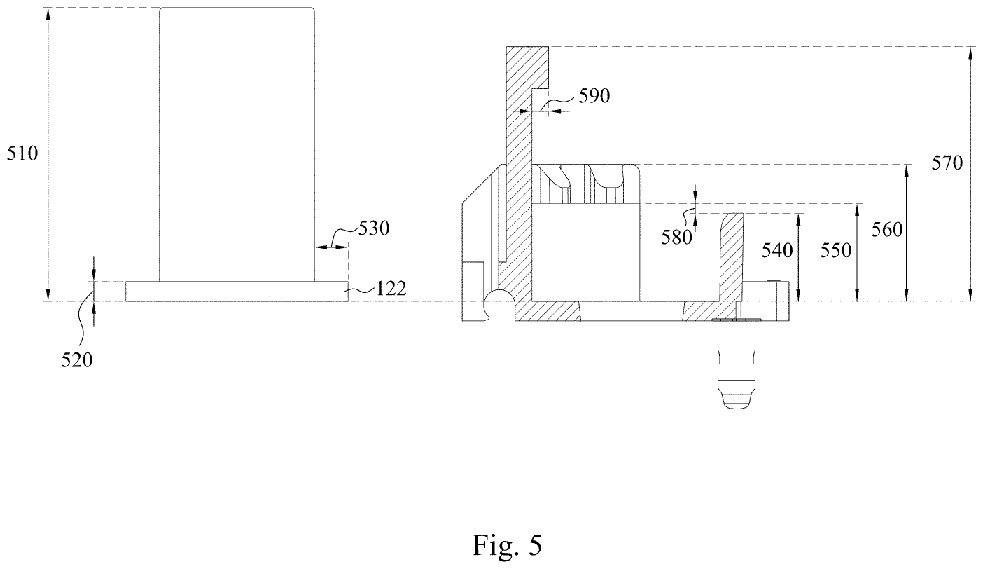

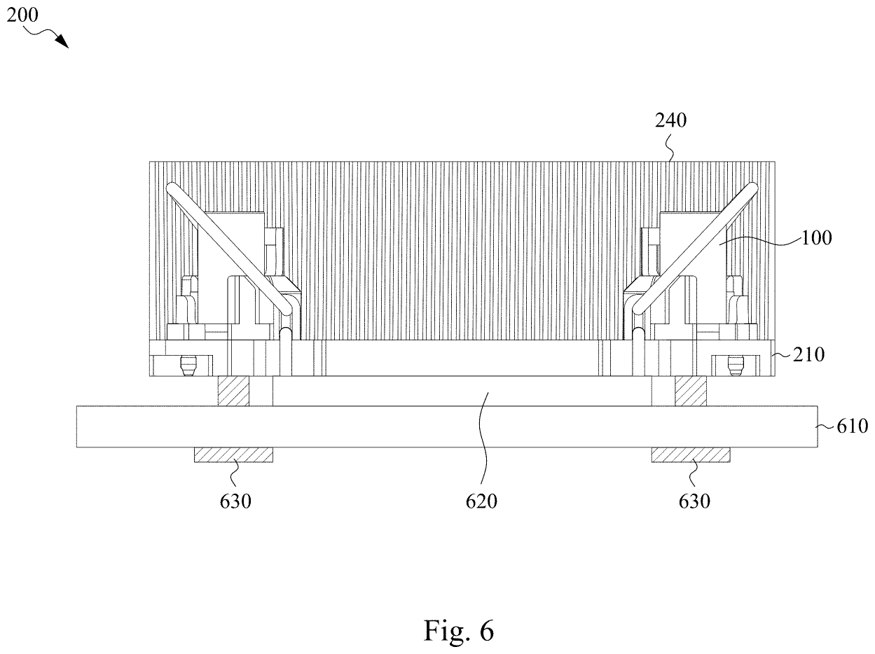

FIG. 1 illustrates a schematic perspective diagram showing a fastening device according to one embodiment of the present invention, FIG. 2 illustrates a partial perspective diagram showing a heat dissipation module with the fastening device, and FIG. 3 illustrates the heat dissipation module viewed from another angle. In addition, FIG. 4 illustrates a fixing base of the fastening device of FIG. 2, FIG. 5 illustrates a side view showing a fixing base and a fixing nut of the fastening device of FIG. 1, and FIG. 6 illustrates a side view showing a carrier board equipped with the heat dissipation module.

Referring to FIG. 1, the fastening device 100 includes a fixing nut 120 and a fixing base 110. The fixing base 110 includes a base plate 118, an anti-falling wall 114, a door piece 112 and an anti-tilt arm 116. The anti-falling wall 114, the door piece 112 and the anti-tilt arm 116 are formed on the base plate 118 and surrounded on the base plate 118. The anti-tilt arm 116 is arranged opposite to the door piece 112.

In some embodiments, simultaneously referring to FIG. 4, the anti-tilt arm 116 can also be arranged on the anti-falling wall 114.

In other embodiments, the anti-tilt arm 116 and the anti-falling wall 114 can also be respectively extended upward from the base plate 118 without departing from the spirit and the scope of the invention.

In addition, the anti-falling wall 114, the door piece 112 and the anti-tilt arm 116 form an accommodation space 117 therebetween, and the fixing nut 120 is rotatably disposed in the accommodation space 117.

In some embodiments, the fixing nut 120 includes a plastic nut, for example, a polyetheretherketone (PEEK) nut. In some embodiments, a flange 122 is formed at the bottom of the fixing nut 120.

Simultaneously referring to FIG. 4 and FIG. 5, a first flange 410 is formed on an anti-tilt arm inside surface 460 of the anti-tilt arm 116 and protrudes toward the fixing nut 120. In addition, a second flange 420 is formed on an anti-falling wall inside surface 470 of the anti-falling wall 114 and also protrudes toward the fixing nut 120.

In some embodiments, the first flange 410 of the anti-tilt arm 116 is located on the upper portion of the anti-tilt arm inside surface 460, and the second flange 420 of the anti-falling wall 114 is located on the upper portion of the anti-falling wall inside surface 470. In other embodiments, the first flange 410 of the anti-tilt arm 116 can be disposed on any portion of the anti-tilt arm inside surface 460, and the second flange 420 of the anti-falling wall 114 can be disposed on any portion of the anti-falling wall inside surface 470 without departing from the spirit and the scope of the invention.

The first flange 410 of the anti-tilt arm 116 can effectively limit the tilt angle of the fixing nut 120 to prevent the fixing nut 120 from falling out of the accommodation space 117. In addition, the second flange 420 of the anti-falling wall 114 can effectively limit the moving distance of the fixing nut 120 up and down. For example, when the fixing nut 120 moves up and the flange 122 of the fixing nut 120 contacts the second flange 420 of the anti-falling wall 114, the fixing nut 120 cannot further move upward, so that the fixing nut 120 can be rotatably arranged in the accommodation space 117 after the fixing nut 120 is pressed into the accommodation space 117 by way of the direction of the door piece 112.

When the fixing nut 120 is disposed in the accommodation space 117, the tilt angle between the fixing nut 120 and the anti-tilt arm 116 is smaller than the tilt angle between the fixing nut 120 and the anti-falling wall 114 and also smaller than the tilt angle between the fixing nut 120 and the door piece 112.

In some embodiments, a height difference 580 between an anti-drop flange bottom height 550 of the anti-falling wall 114 and the door piece height 540 is smaller than the flange height 520 of the fixing nut 120 so as to effectively limit a displacement of the fixing nut 120 in the accommodation space 117.

In some embodiments, an anti-tilt arm height 570 of the anti-tilt arm 116 is equal to about 50% to 80% of a nut height 510 of the fixing nut 120 to effectively prevent from a larger tilt angle of the fixing nut 120 so as to prevent the fixing nut 120 from falling out of the accommodation space 117.

In some embodiments, an anti-falling wall height 560 of the anti-falling wall 114 is equal to about 30% to 50% of the nut height 510 of the fixing nut 120. In addition, a door piece height 540 of the door piece 112 is equal to about 20% to 35% of the nut height 510 of the fixing nut 120.

Hence, the accommodation space 117 is formed by the anti-tilt arm 116, the anti-falling wall 114 and the door piece 112 with three different heights to effectively limit the displacement of the fixing nut 120 in the accommodation space 117, so that the fixing nut 120 can stably dispose in the accommodation space 117 and effectively prevent the fixing nut 120 from falling out of the accommodation space 117 during transportation and assembly.

In some embodiments, an anti-tilt arm flange width 590, i.e. the length of the first flange 410, of the anti-tilt arm 116 is equal to about 0.5 to 1.4 times of the flange width 530 of the fixing nut 120 to effectively limit an tilt angle of the fixing nut 120 without interference to the rotation and movement of the fixing nut 120.

In some embodiments, the fixing base 110 of the fastening device 100 further includes at least one elastic claw 119 formed on a surface, opposite to the anti-tilt arm 116, of the base plate 118. The elastic claw 119 includes an elastic finger 440 and an elastic finger 450, and an opening 430 is formed between the elastic finger 440 and elastic finger 450. The elastic claw 119 passes through the opening of the base board 210 to fix fixing base 110 on the base board 210.

In some embodiments, the fastening device 100 further includes at least one metal fixing hook 130 movably mounted on the fixing base 110 so as to fix the fastening device 100 on a carrier board.

Referring to FIG. 6, the heat dissipation module 200 as illustrated in FIG. 2 and FIG. 3 is installed on a carrier board 610. In FIG. 2 and FIG. 3, the heat dissipation fins 240 of the heat dissipation module 200 are removed to conveniently explain the other components of heat dissipation module 200.

The heat dissipation module 200 includes a base board 210, a heat pipe 220, a metal heat dissipation block 230, a plurality of heat dissipation fins 240 and a plurality of fastening device 100. The fastening devices 100 are disposed around the base board 210 to fix the heat dissipation module 200 on the carrier board 610 so as to cool the electronic component 620.

The heat pipe 220 is disposed in the opening of the base board 210, the metal heat dissipation block 230 is fixed to the bottom surface of the heat pipe 220, and the heat dissipation fins 240 is fixed to the upper surface of the heat pipe 220. In addition, the metal heat dissipation block 230 and the heat dissipation fins 240 are fixed to the base board 210. The metal heat dissipation block 230 is a high thermal conductivity metal block, for example, a copper block.

When the heat dissipation module 200 is fixed on the carrier board 610, the fixing screw 630 is screwed to the fixing nut 120 of the fastening device 100 so that the heat dissipation module 200 stably contacts the electronic component 620, thereby reducing the working temperature of the electronic component 620.

In some embodiments, the fixing screw 630 is arranged on the carrier board 610 or upwardly penetrates through an opening of the carrier board 610. When the fixing screw 630 is arranged on the carrier board 610, the fixing screw 630 can be fixed to the carrier board 610, or the fixing screw 630 is fixed on a second carrier board and the second carrier board is fixed to the carrier board 610 with fixing components without departing from the spirit and the scope of the invention. In some embodiments, the second carrier board is a frame with a central opening. When the second carrier board is a frame with a central opening, the electronic component 620 can locate in the central opening to allow the heat dissipation module 200 directly contacting the electronic component 620 in the central opening to cool the electronic component 620 without departing from the spirit and the scope of the invention.

Accordingly, the fastening device can conveniently fix the heat dissipation module on the carrier board, and the fastening device can be quickly fixed on the base board with the elastic claws. In addition, the fastening device utilizes the anti-tilt arm to effectively limit the tilt angle of the fixing nut, so as to prevent the fixing nut accidentally falling off the fixing base before the fixing nut is fixed to the carrier board.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A fastening device, comprising:
a fixing nut; and
a fixing base, wherein the fixing base comprises:
a base plate;
an anti-falling wall formed on the base plate;
a door piece formed on the base plate; and
an anti-tilt arm, opposite to the door piece, formed on the base plate, wherein the anti-falling wall, the door piece and the anti-tilt arm form an accommodation space, and the fixing nut is rotatably disposed in the accommodation space.

2. The fastening device of claim 1, wherein the fixing base further comprises an elastic claw formed on a surface, opposite to the anti-tilt arm, of the base plate.

3. The fastening device of claim 1, further comprising at least one metal fixing hook movably mounted on the fixing base.

4. The fastening device of claim 1, wherein the anti-tilt arm comprises a first flange protruding toward the fixing nut.

5. The fastening device of claim 4, wherein the anti-falling wall comprises a second flange protruding toward the fixing nut.

6. The fastening device of claim 5, wherein an anti-tilt arm height of the anti-tilt arm is equal to about 50% to 80% of a nut height of the fixing nut.

7. The fastening device of claim 6, wherein an anti-falling wall height of the anti-falling wall is equal to about 30% to 50% of the nut height of the fixing nut.

8. The fastening device of claim 7, wherein a door piece height of the door piece is equal to about 20% to 35% of the nut height of the fixing nut.

9. The fastening device of claim 8, wherein a height difference between an anti-drop flange bottom height of the anti-falling wall and the door piece height is smaller than a flange height of the fixing nut.

10. A heat dissipation module, comprising:
a base board;
a heat pipe disposed on the base board;
a metal heat dissipation block fixed on a surface of the heat pipe;
a plurality of heat dissipation fins fixed on the base board; and
a plurality of fastening devices fixed on the base board, wherein the base board is fixed on a carrier board with a plurality of fixing screws, wherein each of the fastening devices, comprising:
a fixing nut; and
a fixing base, wherein the fixing base comprises:
a base plate;
an anti-falling wall formed on the base plate;
a door piece formed on the base plate; and
an anti-tilt arm, opposite to the door piece, formed on the base plate, wherein the anti-falling wall, the door piece and the anti-tilt arm form an accommodation space, and the fixing nut is rotatably disposed in the accommodation space.

11. The heat dissipation module of claim 10, wherein the fixing base further comprises an elastic claw formed on a surface, opposite to the anti-tilt arm, of the base plate.

12. The heat dissipation module of claim 10, wherein each of the fastening devices further comprises at least one metal fixing hook movably mounted on the fixing base.

13. The heat dissipation module of claim 10, wherein the anti-tilt arm comprises a first flange protruding toward the fixing nut.

14. The heat dissipation module of claim 13, wherein the anti-falling wall comprises a second flange protruding toward the fixing nut.

15. The heat dissipation module of claim 14, wherein an anti-tilt arm height of the anti-tilt arm is equal to about 50% to 80% of a nut height of the fixing nut.

16. The heat dissipation module of claim 15, wherein an anti-falling wall height of the anti-falling wall is equal to about 30% to 50% of the nut height of the fixing nut.

17. The heat dissipation module of claim 16, wherein a door piece height of the door piece is equal to about 20% to 35% of the nut height of the fixing nut.

18. The heat dissipation module of claim 17, wherein a height difference between an anti-drop flange bottom height of the anti-falling wall and the door piece height is smaller than a flange height of the fixing nut.
